(19) United States
(12) Patent Application Publication
(10) Pub. No.: US 2011/0108955 A1
(43) Pub. Date: May 12, 2011

(54) Semiconductor device and manufacturing method

(75) Inventors: Johan Hendrik Klootwijk, Eindhoven (NL); Eugene Timmering, Eindhoven (NL)

(73) Assignee: Koninklijke Philips Electronics N.V., Eindhoven (NL)

(21) Appl. No.: 13/003,602

(22) PCT Filed: Jul. 9, 2009
(86) PCT No.: PCT/IB2009/052982

§ 371 Date: Jan. 11, 2011

(30) Foreign Application Priority Data
Jul. 16, 2008 (EP) 08160537.0

(51) Int. Cl. H01L 29/20

(52) U.S. Cl. 257/615; 257/E29.089

(57) ABSTRACT

The present invention relates to a device (10) comprising a substrate (12) having a front surface (14) and a back surface (24); a semiconductor element (16) provided on the front surface of the substrate; a first passivation layer (18); and a second passivation layer (22) provided on the back surface of the substrate. The present invention also relates to a method of manufacturing such a device.

### FIELD OF THE INVENTION

The present invention relates to a device, in particular a passivated semiconductor device, as well as to a method of manufacturing such a device.

### BACKGROUND OF THE INVENTION

Semiconductor devices may be passivated to make them inactive or less reactive or to protect them against contamination by coating or surface treatment or to reduce leakage currents.

The US patent application publication No. US 2002/0000510 A1 (Matsuda) discloses a photodetector comprising a semiconductor conductive layer, a light absorbing layer, and a wide bandgap layer stacked on a substrate. Further, a passivation film of SiN and a dielectric film of SiO₂ are in turn deposited over the substrate. In addition, a pad electrode is disposed on the dielectric film.

However, a problem that has been observed in for instance GaN lasers is that after passivation, the electrical performance of the device is significantly decreased.

### SUMMARY OF THE INVENTION

It is an object of the present invention to at least partly overcome this problem, and to provide an improved semiconductor device with more proper device behavior also after passivation.

This and other objects that will be apparent from the following description are achieved by a device and method according to the appended independent claims.

According to an aspect of the invention, there is provided a device comprising a substrate having a front surface and a back surface; a semiconductor element provided on the front surface of the substrate; a first passivation layer; and a second passivation layer provided on the back surface of the substrate.

The above-mentioned decrease in device performance is mainly caused by the mechanical stress in the passivation layer, as realized from experiments carried out by the present inventors. To this end, by using multiple passivation layers, stress tuning of the passivation structure may be achieved, whereby the creation of electron hole pairs, induced by the piezoelectric effect, may be directly influenced. As an important result, leakage currents, caused by this phenomenon, may be reduced significantly. To achieve the stress tuning using multiple passivation layers, the first passivation layer may have an internal compression stress and the second passivation layer may have an internal tensile stress, e.g. Preferably, for light emitting diode (LED) applications, the resulting stress that acts on the remaining device does not equal zero, for optimal performance. Further, providing the second passivation layer on the back surface is beneficial in that it may be provided following formation of other elements (e.g. the semiconductor element) on the front surface of the device, in particular without having to tamper with the element(s) on the front surface. That is, the second layer on the back surface can always be applied, independent of the presence of any other passivation layer on e.g. the front surface of the device. This provides much freedom in tuning the stress of the device. Also, the device performance may be checked between deposition of the first and second passivation layers.

In one embodiment, the first passivation layer is provided over the front surface of the substrate. That is, there is one passivation layer on the top of the substrate (front surface) and one passivation layer on the bottom of the substrate (back surface).

In another embodiment, the first passivation layer is provided on the second passivation layer. That is, there is a dual passivation layer stack on the back surface of the substrate.

In yet another embodiment, the device further comprises at least one contact connected to the semiconductor element and extending through the first passivation layer provided over the front surface of the substrate, wherein the second passivation layer provided on the back surface of the substrate is replaced by another second passivation layer provided over the first passivation layer and partly covering the at least one contact. Hence, in this embodiment, there is no passivation layer on the back surface of the substrate. The second layer on top of the device “simulates” a scratch protection layer, known from silicon device technology.

The present invention is particularly useful for devices with III-V based semiconductor elements (i.e. compounds with at least one group III element and at least one group V element from the periodic table), for instance III-V light emitting diodes or III-V bipolar transistors, as devices with these elements may suffer significantly from degraded performance following conventional passivation. In fact, the present invention can advantageously be applied to any direct bandgap material (e.g. InP, GaAs, GaN, GaP).

The passivation layers may be dielectric layers. In fact, any layer that can be applied to the device without destroying it (i.e. deposited at low temperature without consuming any part of the underlying elements of the device) could be used.

According to another aspect of the invention, there is provided a method of manufacturing a device comprising a first passivation layer, which method comprises: providing a substrate having a front surface and a back surface; providing a semiconductor element on the front surface of the substrate; and providing a second passivation layer on the back surface of the substrate. This aspect may exhibit similar features and advantages as the previous aspect of the invention.

### BRIEF DESCRIPTION OF THE DRAWINGS

These and other aspects of the present invention will now be described in more detail, with reference to the appended drawings showing currently preferred embodiments of the invention.

FIGS. 1a and 1b schematically illustrate a semiconductor device according to one embodiment of the invention.

FIGS. 2a and 2b schematically illustrate a semiconductor device according to another embodiment of the invention.

FIGS. 3a and 3b schematically illustrate a semiconductor device according to yet another embodiment of the invention.

### DETAILED DESCRIPTION

In the present application, where a first entity is provided “on” or “over” a second entity, the first entity may be provided directly on the second entity, or with at least one intermediate layer or film or the like between the first and second entities, as the case may be. Also, “first” and “second” passivation layers does not necessarily mean that the first layer is applied before the second.

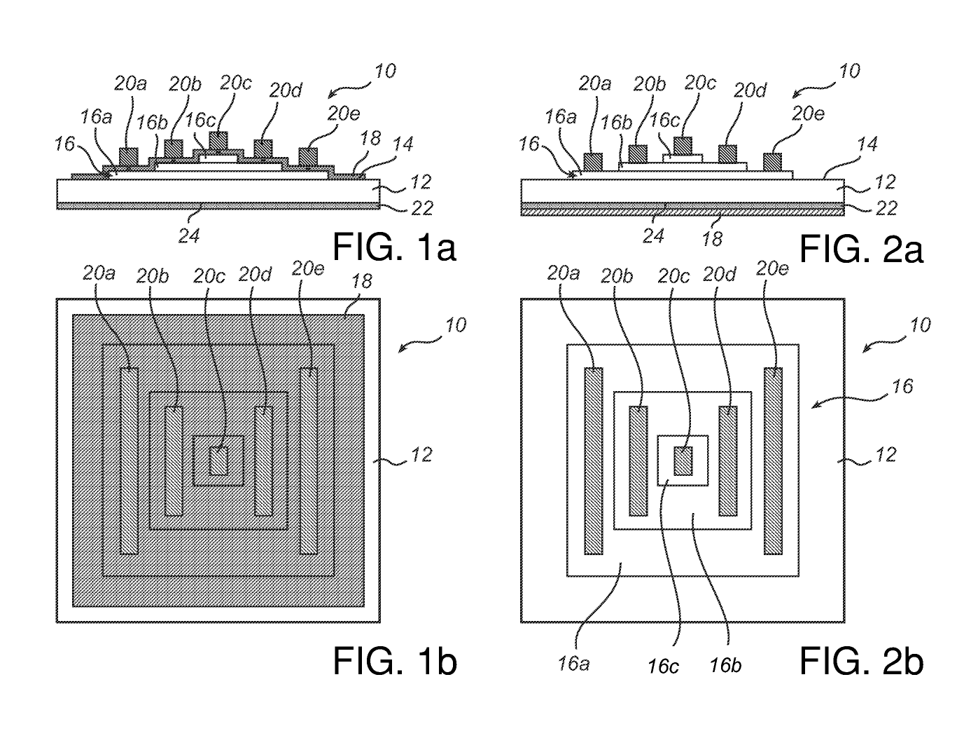

FIG. 1a is a cross-sectional side view and FIG. 1b is a top view of a semiconductor device 10 according to one embodiment of the invention.

The device 10 comprises a substrate 12, e.g. a silicon plate. On the front surface 14 of the substrate 12, a transistor 16 is processed. The transistor 16 comprises from bottom to top a collector 16a, a base 16b, and an emitter 16c in a mesa configuration. Further, a first dielectric passivation layer 18 is provided over the front surface 14 of the substrate 12, i.e. on the transistor 16 and on a portion of the front surface 14 of the substrate 12 not covered by the transistor 16. The passivation layer 18 consist of a wide bandgap material (or at least a larger bandgap than the materials to be passivated). The passivation layer 18 may for instance be made of deposited SiO₂ (may be plasma enhanced), Si₃N₄, polyamide, BCB, etc. In addition, the device 10 comprises metal contacts 20a-20e connected to the transistor 16 and extending through the first passivation layer 18, as illustrated. Namely, contacts 20a and 20e are connected to the collector 16a, contacts 20b and 20d are connected to the base 16b, and contact 20c is connected to the emitter 16c. A top portion of each contact 20a-20e extending outside or over the first passivation layer 18 may be wider than the rest of the contact, to facilitate connection to external entities (not shown).

Further, the device 10 comprises a second dielectric passivation layer 22 provided on the back surface 24 of the substrate 12, which back surface 24 is opposite the front surface 14 of the substrate 12. The second passivation layer 22 may be of the same type as the first passivation layer 18.

In a method of manufacturing the device 10 of FIGS. 1a-1b, the substrate 12 is first provided. Then, the transistor 16 is processed on top of the substrate 12. The transistor 16 may be a so-called MESA device, which is first grown as a full epi-stack and subsequently etched to realize the different layers (the collector 16a, base 16b, and emitter 16c). Then, the first passivation layer 18 is deposited on top of the device realized thus far. After that, contacts holes are etched in the passivation layer 18 to accommodate the electrical contacts 20a-20e which are subsequently provided to the device. Finally, the second passivation layer 22 is deposited on the backside of the substrate 12.

FIG. 2a is a cross-sectional side view and FIG. 2b is a top view of a semiconductor device 10 according to another embodiment of the invention.

The device 10 comprises a substrate 12, e.g. a silicon plate. On the front surface 14 of the substrate 12, a transistor 16 is processed. The transistor 16 comprises from bottom to top a collector 16a, a base 16b, and an emitter 16c in a mesa configuration. In addition, the device 10 comprises metal contacts 20a-20e arranged directly on the transistor 16, as illustrated. Namely, contacts 20a and 20e are connected to the collector 16a, contacts 20b and 20d are connected to the base 16b, and contact 20c is connected to the emitter 16c.

Further, the device 10 comprises a “second” dielectric passivation layer 22 provided on the back surface 24 of the substrate 12, as well as a “first” dielectric passivation layer 18 provided on the passivation layer 22. Each of the passivation layers 18 and 24 consist of a wide bandgap material (or at least a larger bandgap than the materials to be passivated). The passivation layers 18 and 22 may for instance be made of deposited SiO₂ (may be plasma enhanced), Si₃N₄, polyamide, BCB, etc.

In a method of manufacturing the device 10 of FIGS. 2a-2b, the substrate 12 is first provided. Then, the transistor 16 is processed on top of the substrate 12. The transistor 16 may be a so-called MESA device, which is first grown as a full epi-stack and subsequently etched to realize the different layers (the collector 16a, base 16b, and emitter 16c). Then, the electrical contacts 20a-20e are put directly on the transistor 16 using a so-called lift of resist. Finally, the passivation layer 22 is deposited on the backside of the substrate 12, and the passivation layer 18 is in turn deposited on the passivation layer 22, forming a dual passivation layer stack on the back surface 24. Alternatively, the layers 18 and 22 may be a prefabricated stack which is provided on the back surface 24 of the substrate 12.

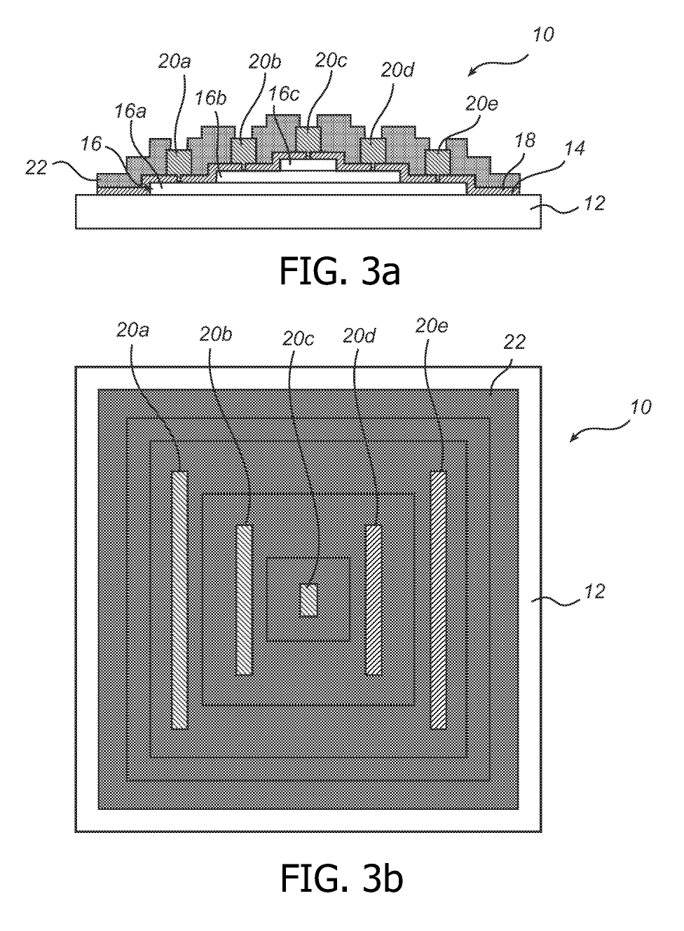

FIG. 3a is a cross-sectional side view and FIG. 3b is a top view of a semiconductor device 10 according to yet another embodiment of the invention.

The device 10 comprises a substrate 12, e.g. a silicon plate. On the front surface 14 of the substrate 12, a transistor 16 is processed. The transistor 16 comprises from bottom to top a collector 16a, a base 16b, and an emitter 16c in a mesa configuration. Further, a first dielectric passivation layer 18 is provided over the front surface 14 of the substrate 12, i.e. on the transistor 16 and on a portion of the front surface 14 of the substrate 12 not covered by the transistor 16. The passivation layer 18 consist of a wide bandgap material (or at least a larger bandgap than the materials to be passivated). The passivation layer 18 may for instance be made of deposited SiO₂ (may be plasma enhanced), Si₃N₄, polyamide, BCB, etc. In addition, the device 10 comprises metal contacts 20a-20e connected to the transistor 16 and extending through the first passivation layer 18, as illustrated. Namely, contacts 20a and 20e are connected to the collector 16a, contacts 20b and 20d are connected to the base 16b, and contact 20c is connected to the emitter 16c. A top portion of each contact 20a-20e extending outside or over the first passivation layer 18 may be wider than the rest of the contact, to facilitate connection to external entities (not shown).

Further, the device 10 comprises a second dielectric passivation layer 22 provided over the first passivation layer 18 and partly covering each of the contacts 20a-20e. Namely, the second passivation layer 22 partly covers the wider top portion of each contact 20a-20e, as illustrated. Hence, the wider top portions of the contacts 20a-20e are intermediate to the two passivation layers 18 and 22. The second passivation layer 22 may be of the same type as the first passivation layer 18.

In a method of manufacturing the device 10 of FIGS. 3a-3b, the substrate 12 is first provided. Then, the transistor 16 is processed on top of the substrate 12. The transistor 16 may be a so-called MESA device, which is first grown as a full epi-stack and subsequently etched to realize the different layers (the collector 16a, base 16b, and emitter 16c). Then, the first passivation layer 18 is deposited on top of the device realized thus far. After that, contacts holes are etched in the passivation layer 18 to accommodate the electrical contacts 20a-20e which are subsequently provided to the device. Then, the second passivation layer 22 is deposited over the first passivation layer 18 and over the contacts 20a-20e, after which the contacts 20a-20e may be partly opened or contacted using a so-called CB (contact to bondpad) mask.

In each of the above embodiments, one additional layer is added to the device to compensate for the mechanical stress induced by a single passivation layer. In other words, by using two passivation layers 18 and 22, stress tuning of the passivation structure may be achieved, whereby the creation of electron hole pairs in the transistor 16, induced by the piezoelectric effect, may be directly influenced. As an important result, leakage currents in the transistor 16, caused by this phenomenon, may be reduced significantly. Hence, the two passivation layers 18 and 22 should be so arranged that the final mechanical stress that is put on the underlying or intermediate structure is such that the piezo electric effect is not induced, or at least reduced to a significant degree. In other words, the second layer is added to tune the stress such that leakage currents are minimized. To achieve the stress tuning, the first passivation layer 18 may for instance have an internal compression stress and the second passivation layer 22 may have an internal tensile stress, or vice versa. Also, in particular in case the device 10 comprises a light emitting diode instead of the transistor 16, the resulting stress that acts on the remaining device should not be equal to zero, for optimal performance, i.e. proper working pn-junctions with low leakage currents. Typically, the resulting stress is about 150 Mpa tensile stress for InP-based devices.

The person skilled in the art realizes that the present invention by no means is limited to the preferred embodiments described above. On the contrary, many modifications and variations are possible within the scope of the appended claims. For instance, at least one further passivation layer in addition to the present two passivation layers may be added to the device, to compensate for the mechanical stress induced by a single passivation layer.

1. A device, comprising:
a substrate having a front surface and a back surface;
a semiconductor element provided on the front surface of the substrate;
a first passivation layer; and
a second passivation layer
wherein one of said first passivation layer and said second passivation layer is arranged to have a predetermined internal compression stress, while the remaining first or second passivation layer is arranged to have a predetermined internal tensile stress, thereby providing a predetermined stress tuning of the resulting mechanical stress caused by the first passivation layer and the second passivation layer

2. A device according to claim 1, wherein the first passivation layer is provided over the front surface of the substrate.

3. A device according to claim 1, wherein the first passivation layer is provided on the second passivation layer.

4. A device according to claim 2, further comprising at least one contact (20a-20e) connected to the semiconductor element and extending through the first passivation layer provided over the front surface of the substrate, wherein the second passivation layer provided over the first passivation layer and partly covering the at least one contact.

5. A device according to claim 1, wherein the semiconductor element is a III-V based element.

6. A device according to claim 1 wherein the passivation layers are dielectric layers.

7. (canceled)

8. A device according to claim 1, wherein the second passivation layer is provided over the back surface of the substrate.
